(19) United States
(12) Patent Application Publication
(10) Pub. No.: US 2026/0286569 A1
(43) Pub. Date: Sep. 24, 2026

(54) SYSTEMS AND METHODS FOR HETEROGENEOUS DIAMOND FACE SYNTHESIS FOR IN-SITU THREE-DIMENSIONAL DOPANT AND STRUCTURE LOCALIZATION

(71) Applicants: UCHICAGO ARGONNE, LLC, Chicago, IL (US); THE UNIVERSITY OF CHICAGO, Chicago, IL (US)

(72) Inventors: Nazar DELEGAN, Chicago, IL (US); Joseph P. HEREMANS, Chicago, IL (US); David AWSCHALOM, Chicago, IL (US)

(73) Assignees: UCHICAGO ARGONNE, LLC, Chicago, IL (US); THE UNIVERSITY OF CHICAGO, Chicago, IL (US)

(21) Appl. No.: 19/569,723

(22) Filed: Mar. 17, 2026

Related U.S. Application Data
(60) Provisional application No. 63/773,902, filed on Mar. 18, 2025.

(51) Int. Cl. C30B 25/18; C30B 25/20; C30B 29/04; C30B 31/00; C30B 33/12

(52) U.S. Cl. CPC C30B 25/186; C30B 25/20; C30B 29/04; C30B 31/00; C30B 33/12

(57) ABSTRACT

A method includes determining a plurality of ratios of growth rates. The method includes etching an array of pits into a first portion of a substrate including single crystal diamond. The method includes filling each pit of the array of pits with a dopant at a first growth rate based on the plurality of ratios of growth rates to form an array of filled pits. The method includes forming a portion of an overlayer on a second portion of the substrate adjacent to the array of pits at a second growth rate less than the first growth rate. The overlayer includes the portion of the overlayer on the second portion of the substrate and dopant disposed on the array of filled pits. The method includes removing the overlayer to expose the second portion of the substrate.

### CROSS-REFERENCE TO RELATED APPLICATION

This application claims priority to U.S. Provisional Patent App. No. 63/773,902 filed Mar. 18, 2025, the contents of which is incorporated herein by reference in its entirety.

### STATEMENT OF GOVERNMENT INTEREST

This invention was made with government support under Contract No. DE-AC02-06CH11357 awarded by the United States Department of Energy to UChicago Argonne, LLC, operator of Argonne National Laboratory. The government has certain rights in the invention.

### TECHNICAL FIELD

The present disclosure relates generally to heterogeneous diamond face synthesis.

### BACKGROUND

Three-dimensional (3D) doping can be stochastic in nature.

### SUMMARY

Diamond homoepitaxy can be limited to uniform two-dimensional (2D) growth and doping due to a focus on growing well-controlled homogeneous diamond faces. Other 3D localized approaches to doping diamond rely on implantation and fabrication, which limits performance of devices made using these techniques. The systems and methods of the present disclosure are directed to techniques to take advantage of the different growth rates of different diamond faces and along different directions.

One aspect of the present disclosure is directed to a method. The method includes determining a plurality of ratios of growth rates. The method includes etching an array of pits into a first portion of a substrate. The substrate includes single crystal diamond. The method includes filling each pit of the array of pits with a dopant at a first growth rate based on the plurality of ratios of growth rates to form an array of filled pits. The method includes forming a portion of an overlayer on a second portion of the substrate adjacent to the array of pits at a second growth rate less than the first growth rate. The overlayer includes (1) the portion of the overlayer on the second portion of the substrate and (2) dopant disposed on the array of filled pits. The method includes removing the overlayer to expose the second portion of the substrate.

Another aspect of the present disclosure is directed to an assembly. The assembly includes a doped diamond crystal formed by determining a plurality of ratios of growth rates. The doped diamond crystal is formed by etching an array of pits into a first portion of a substrate comprising single crystal diamond. The doped diamond crystal is formed by filling each pit of the array of pits with a dopant at a first growth rate based on the plurality of ratios of growth rates to form an array of filled pits. The doped diamond crystal is formed by forming a portion of an overlayer on a second portion of the substrate adjacent to the array of pits at a second growth rate less than the first growth rate. The overlayer includes (1) the portion of the overlayer on the second portion of the substrate and (2) dopant disposed on the array of filled pits. The doped diamond crystal is formed by removing the overlayer to expose the second portion of the substrate.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF DRAWINGS

The foregoing and other features of the present disclosure will become more fully apparent from the following description and appended claims, taken in conjunction with the accompanying drawings. Understanding that these drawings depict only several implementations in accordance with the disclosure and are, therefore, not to be considered limiting of its scope, the disclosure will be described with additional specificity and detail through the use of the accompanying drawings.

FIGS. 1A and 1B illustrate crystallographic faces of diamond, according to an example implementation.

FIG. 2 illustrates a schematic diagram of a top view of a substrate and side views of two pit geometries, according to an example implementation.

FIG. 3 illustrates an example etching pattern for characterizing α, β, and γ, according to an example implementation.

FIG. 4 illustrates etch feature geometries, according to an example implementation.

FIG. 5 illustrates a schematic flow diagram of a method for heterogeneous diamond face synthesis, according to an example implementation.

FIGS. 6A-6D illustrate a doped diamond crystal formed by a method for heterogeneous diamond face synthesis, according to an example implementation.

FIGS. 7A and 7B illustrate atomic force microscopy images, according to an example implementation.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

Following below are more detailed descriptions of various concepts related to, and implementations of, methods, apparatuses, and systems for heterogeneous diamond face synthesis. The various concepts introduced above and discussed in greater detail below may be implemented in any of numerous ways.

Diamond homoepitaxial growth can be intrinsically limited to two-dimensional (2D) doping. For example, while three-dimensional (3D) growth in island and 3D nucleated growth regimes can be achieved, these are stochastic in nature. Step-flow growth is a much more deterministic growth approach, notably when localizing dopants in depth, allowing for 2D localization of defects.

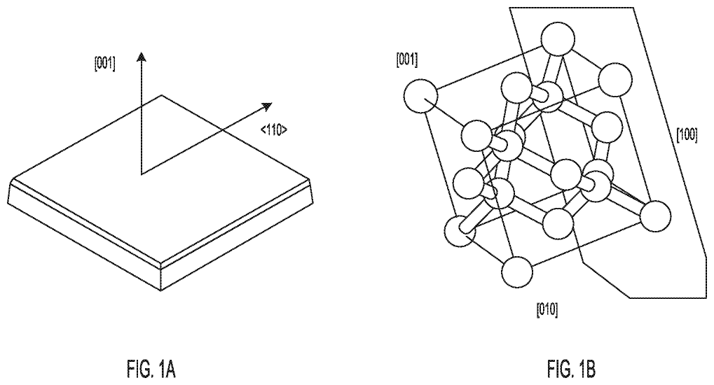

FIGS. 1A and 1B illustrate crystallographic faces of diamond. FIG. 1A shows an example of crystallographic orientations of a diamond substrate. FIG. 1B shows the <100> family of cardinal directions relative to a diamond unit cell and the [001] plane. The various faces of diamond (e.g. [001] vs. [111]) follow different thermodynamic growth behavior during diamond synthesis. Statements about comparative growth capabilities can be relative to step-flow or any other controlled growth regimes that allow for deterministic and uniform growth and doping.

Diamond homoepitaxy can focus growing on well-controlled homogeneous diamond faces. This can limit growth to uniform 2D growth and doping. Because of this, most 3D localized approaches for achieving doping of diamond rely on implantation and fabrication or a mix of the two after diamond growth, greatly limiting device and quantum performance.

The systems and methods of the present disclosure are directed to a technique that can exploit the differing growth rate of different diamond faces to achieve technologically critical results such as (1) deterministic 3D localized in-situ doping of diamond, with nanometer control of nitrogen and/or other dopants, (2) in-situ nitrogen-vacancy (NV) synthesis of preferentially oriented defects in the case of (111) facet growth, (3) controlled synthesis of heterogeneous diamond faces, (4) co-localization of nuclear 13C spins within the fill volume, allowing for a locally controllable nuclear spin environment, (5) deterministic localization and orientation of NV centers (and other similar spin-defects) in diamond, and/or (6) spatial localization of homoepitaxial chemical vapor deposition (CVD) overgrowth on-chip or on a diamond substrate. The systems and methods of the present disclosure can include heterogeneous diamond face synthesis for in-situ three-dimensional dopant and structure localization.

The ratio of growth rates of different faces of diamond can be expressed relative to the [001] face, with growth parameters α, β, and γ defined as:

$$α = \frac{{V}_{[ 100 ]}}{{V}_{[ 111 ]}} \cdot √ 3 ,$$

$$β = \frac{{V}_{[ 100 ]}}{{V}_{[ 110 ]}} \cdot √ 2 ,$$

$$γ = \frac{{V}_{[ 100 ]}}{{V}_{[ 113 ]}} \cdot √ 11.$$

In one example, for typical growth conditions in the step-flow growth on a [001] face of diamond, a is expected to be in the range of 0.2 and 1.5. However, a can vary greatly and be dictated by a number of factors including relative methane concentration, overall growth pressure, and/or plasma kinetics. The growth parameter a can be function of methane concentration and/or temperature.

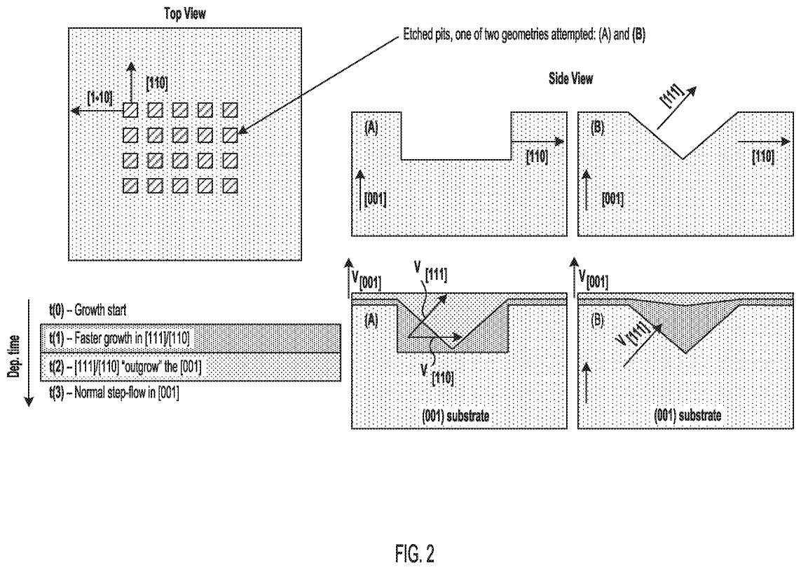

FIG. 2 illustrates a schematic diagram of a top view of a substrate and side views of two pit geometries. For a given set of growth conditions, α, β, and γ (alongside sample miscut and kerf angular tolerances) can be characterized. Characterizing the growth parameters results in the ability to create intentionally exposed areas of the associated faces (e.g. [111] exposed on otherwise [001] face) and to predict the fill speeds of features (e.g., pits). If preferential growth in the <111> direction is desired, the lowest parameter a can be sought. In one example, given typical growth parameters, α is between 0.5 and 1.5, leading to a V₁₀₀/V₁₁₁ between 0.29 and 0.87. This allows filling of the exposed features significantly faster than any other effective overgrowth on the un-patterned [001] face.

The geometries presented in (A) and (B) of FIG. 2 are both possible, but should be independently deconvoluted as they relate to the contributions from 3 and a. The method can be used for sub-micron features, which are relevant for quantum and microelectronic technologies. For this, precise depth and etch-pit wall control, as well as either in-situ or post-situ isotropic growth etching to remove any undesired [001] face overgrowth (e.g., overgrowth above the etch-defined feature or pit). Different growth regions can be marked by different deposition times (e.g., t(0), t(1), t(2), t(3)). The deposition time t(0) can be less than t(1), t(2), and t(3). The deposition time t(1) can be less than t(2) and t(3). The deposition time t(2) can be less than t(3). The deposition time t(3) can be greater than t(2), t(1), and t(0). The deposition time t(2) can be greater than t(1), and t(0). The deposition time t(1) can be greater than t(0). For example, at t(0), growth (e.g., deposition) of dopant can start. At t(1), the dopant can have faster growth in the [111] and/or [110] direction. At t(2), the dopant can grow faster in the [111] and/or [110] direction than in the [001] direction. At t(3), the dopant can undergo step-flow growth in the [001] direction.

The method (e.g., process) can include characterizing α, β, and γ parameters for a given set of growth conditions. The method can include using optical or e-beam lithography to define an array of pits (e.g., micro-pits, nano-pits) on a (100)-oriented diamond substrate followed by a combination of isotropic and non-isotropic RIE etching. The method can include performing overgrowth and adjusting α, β, and γ. Once a smooth surface is achieved, the method can include a sample-wide isotropic RIE etching or, if in-situ approaches are preferred, in-situ hydrogen (or oxygen enriched hydrogen) plasma etching to remove any undesired residual delta-doping layer. The method can include overgrowing the sample and capping the localized areas.

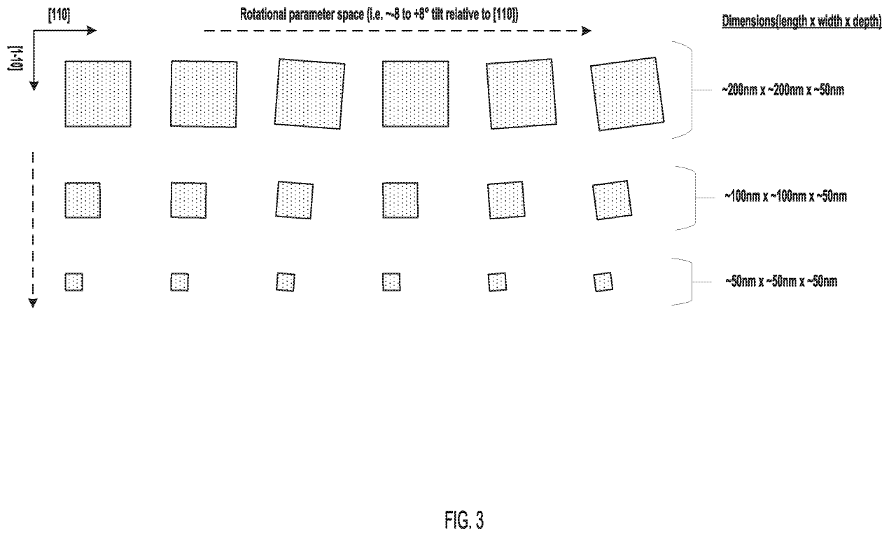

Regarding the pits, the pit walls can lie along the <110> family of directions since the varying growth rate of diamond faces are to be exploited to preferentially fill these pits. The pit walls can have normal vectors in the [110] and [111] directions, respectively, as shown in (A) and (B) of FIG. 3. Inverted pyramidal pits that would maximize {111} face exposure can contribute to preferential NV orientation. This technique can be extrapolated for the creation of line-like moat features for the creation of in-line NVs and other similar applications.

In one example, for overgrowth, a growth rate along the <111> direction is about 1.1 to 3.4 times faster compared to the growth rate along the <001> direction. Growth in the <111> and <011> directions can ensure that the pits fill much faster than the [001] surface recedes, leading to a point where the four sidewall growth vectors meet at the [001] growth surface, at which point smooth substrate growth can continue.

FIG. 3 illustrates an example etching pattern for characterizing α, β, and γ. This pattern accounts for kerf mismatch. To check sample miscut dependence, a series of sample surfaces at different miscut angles can be used. The various sample surfaces can have a rotational parameter space of, for example, between about −10° to +100 tilt relative to [110]. For example, the sample surfaces can have a tilt relative to [110] of between −10° to −8°, −10° to −6°, −10° to −4°, −10° to −2°, −10° to 0°, −10 to +2°, −10 to +4°, −10 to +6°, −10 to +8°, −10 to +10°, −8° to −6°, −8° to −40−80 to −20, −80 to 0, −80 to +20, −80 to +40, −80 to +60, −80 to +80, −80 to +100, −60 to −40, −60 to −20, −60 to 0, −60 to +20, −60 to +40, −60 to +60, −60 to +80, −60 to +100, −40 to −20, −40 to 0, −40 to +20, −40 to +40, −40 to +60, −40 to +80, −40 to +100, −20 to 0, −20 to +20, −20 to +40, −20 to +60, −20 to +80, −20 to +10, 0° to +2, 0° to +4, 0° to +6, 0° to +8, 0° to +100, +20 to +40, +20 to +60, +2° to +8°, +2° to +10°, +4° to +6°, +4° to +8°, +4° to +10°, +6° to +8°, +6° to +10°, or +8° to +10°. The mismatch can influence the optimal growth conditions for that particular kerf and/or miscut orientation.

In one example, the series of samples surfaces can have sizes ranging from about 25 nm to about 300 nm in width, about 25 nm to about 300 nm in length, and about 25 nm to about 300 nm in depth. For example, each sample can have dimensions (e.g., length, width, and depth) of about 200 nm (length) by about 200 nm (width) by about 50 nm (depth). Each sample can have dimensions of about 100 nm by about 100 nm by about 50 nm. Each sample can have dimensions of about 50 nm by about 50 nm by about 50 nm. Each sample can have dimensions greater than 200 nm or less than 50 nm. The series of samples surfaces can be about 1 μm apart on the substrate. The series of samples surfaces can be separated by a distance that would make them distinguishable via atomic force microscopy (AFM) or other profilometry approaches, yet easy to find on the substrate. The sample surfaces can have dimensions ranging from the nanometer scale to the micrometer scale. For example, the smallest fabricable features of the sample surfaces can be on the order of 50 nm. The smallest fabricable features of the sample surfaces can be on the order of a few microns to hundreds of microns.

For a given set of growth conditions, α, β, and γ and substrate miscut/kerf tolerance can be characterized. The following can provide a template to how α, β, and γ and substrate miscut/kerf for each substrate batch and growth recipe can be characterized such that the methods presented herein can be applied. The processing flow can include using optical or e-beam lithography to define an array of micro/nano-pits on a (100)-oriented diamond substrate followed by a combination of isotropic and non-isotropic RIE etching, exposing pit walls along the <110> family of directions as shown in FIG. 3. The processing flow can include performing overgrowth and picking a series of recipes that vary α, β, and γ. The processing flow can include performing growth on the order of 10 minutes to 60 minutes depending on the projected α, β, and γ. The processing flow can include performing a series of experimental conditions or growth times on a variety of similar substrates. The processing flow can include performing AFM of the etch patterns and characterizing the fill amount. The growth rate ratios (e.g., face growth rate ratios) can be determined for a given set of growth conditions. For example, the growth rates can be determined for the given set of growth conditions, and the ratios of the growth rates can be determined based on the growth rates for each growth condition.

The growth ratios can be calculated based on AFM, other profilometry techniques, or secondary ion mass spectrometry (SIMS) depth characterization of template overgrowth. The model shown in FIG. 2 can be used to approximate the growth time needed to fill a given feature geometry. However, both situations shown in FIG. 2 ignore the contribution from V_{[110]}, as that growth rate component only serves to fill the pit, not catch up with growth in the [001] direction.

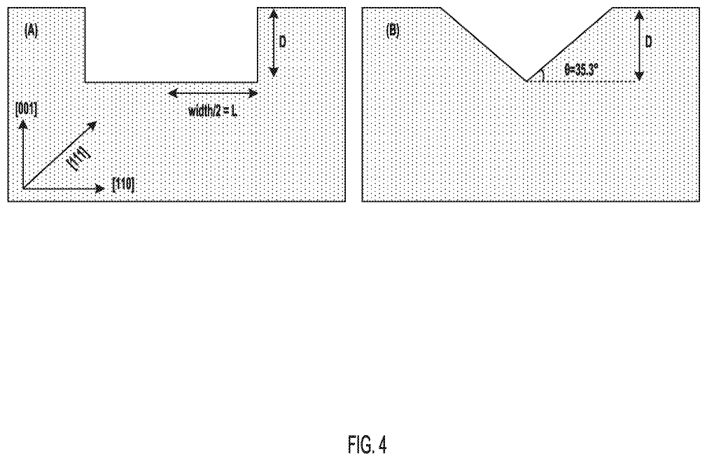

FIG. 4 illustrates etch feature geometries as they relate to various crystal facet growth speeds. The growth time to fill the feature and flatten the surface can be approximated with ([001] defined as \vec{y} and [110] defined as \vec{−x}), as shown in Eq. 1.

$$Growth Time t \approx {D}^{- 1} \cdot {V}_{[ 001 ]} \cdot ( sin ( 54.7 ° ) \cdot \frac{\sqrt{3}}{α} - 1 ) \qquad Eq . 1$$

In the case of geometry (A), the maximum symmetric feature width (square) can therefore be expressed as shown in Eq. 2.

$$Maximum feature width \approx 2 \cdot t \cdot {V}_{[ 001 ]} \cdot ( \frac{\sqrt{3}}{α} \cdot cos ( 54.7 ° ) + \frac{\sqrt{2}}{β} ) \qquad Eq . 2$$

These relationships can lead to the etch pattern presented in FIG. 3. The size variability can allow for more precise determination of the α and β parameters, and the “tilt” feature can serve to correct for substrate kerf miscut and provide the sensitivity of this approach to slight crystallographic misalignment.

The array of pits can be defined using isotropic and non-isotropic etching for template face exposure. In one example, the etching process fulfils the following criteria and/or has the following characteristics. First, the etching process has an etching resolution of about 1-2 nm. Assuming a 10 to 20-second active radical residency time in most ICP-RIE etchers, a etch rate of less than 5 nm/min can be a target for this process. Second, the etching should not alter the surface chemistry such that pre-growth hydrogen plasma cannot restore a pristine C sp³ surface. Third, the post-etched surface should maintain low roughness for optimal growth (e.g., less than 0.3 nm RMS). Fourth, the etch isotropy is controlled to either expose specific diamond crystal planes or achieve perfectly vertical sidewalls.

An oxygen-based dry ICP/RIE approach can be used for isotropic and non-isotropic etching. This approach demonstrates control over side wall facet exposure. In one example, he process follows the following template. (1) Start with <0.3 nm RMS roughness diamond (e.g., substrate) that has been post-polishing treated (ICP/RIE etched). (2) Ensure that {100} and {110} faces are mapped out (typically, electronic grade e6 diamond is (001) top and {110} sides). (3) Sonicate the substrate in DI/IPA for a couple of minutes to remove surface dirt. (4) O₂ plasma asher descum (100 W/10 sccm for ~1-5 min). (5) Dehydrate chip for 5 minutes at 180° C. (6) Deposit Al₂O₃(~60 nm) using ALD at 150° C. (7) Write etch hard mask features including a) spin 950K PMMA A4, b) bake for 5 minutes at 180° C. (protect from UV thereafter), c) deposit 20 nm Au or Cr as a conduction layer, d) write mask, use low beam current (~0.3 nA) with ~1300 uC·cm⁻² or smaller (if multi-pass), e) strip metal (Au/Cr) (acid), and e) mix MIBK:IPA in 1:3, let cool to 7° C., develop the chip (90 sec manual agitation followed by 60 sec of IPA, rinse with DI, N₂ dry). (8) Remove resist. (9) Etch features with a variety of recipes depending on the desired facet exposure. In one example, the recipe includes 30 sccm O₂, 2 sccm Cl at 10 mTorr, ICP 200 W, Bias 50 W. In another example, the recipe includes 30 sccm O₂ at 10 mTorr, ICP 200 W, Bias 0 W. (10) HF dip to remove Al₂O₃. (11) AFM check post-etch roughness and etch depth. (12) For SEM, deposit 2 nm of amorphous carbon using the Nexdep as a conduction layer. Cr can be used as a conduction layer. The process described above is an example, but it is understood that the process can be optimized.

The overgrowth layer can be removed via in-situ post synthesis etching with H₂ or oxygen enriched H₂ plasma etching. After growth, the growth chamber can be switched (removal of methane precursor) into H₂ etching mode. Typically, H₂ etching is slow (e.g., <5 nm/h) so a small amount of oxygen can be added in the plasma mixture to compensate for this. The exact etching rate can be calibrated for each substrate batch and reactor conditions.

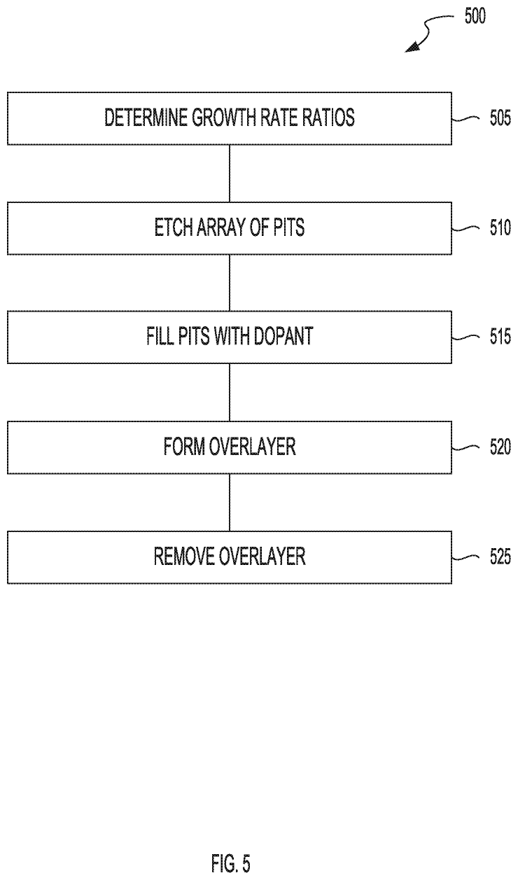

FIG. 5 illustrates a schematic flow diagram of a method 500 for heterogeneous diamond face synthesis. In brief summary, the method 500 can include determining growth rate ratios (BLOCK 505). The method 500 can include etching an array of pits (BLOCK 510). The method 500 can include filling the pits with dopant (BLOCK 515). The method 500 can include forming an overlayer (BLOCK 520). The method 500 can include removing the overlayer (BLOCK 525).

The method 500 can include determining growth rate ratios (BLOCK 505). For example, the method 500 includes determining a plurality of ratios of growth rates. The plurality of ratios of growth rates can include a first ratio of growth rates, a second ratio of growth rates, and/or a third ratio of growth rates. In one example, the first ratio of growth rates is defined by

$$α = \frac{{V}_{[ 100 ]}}{{V}_{[ 111 ]}} \cdot √ 3.$$

The first ratio of growth rates can include a ratio proportional to the growth rate of the material in [100] direction to the growth rate of the material in the [111] direction. In another example, the second ratio of growth rates is defined by

$$β = \frac{{V}_{[ 100 ]}}{{V}_{[ 110 ]}} \cdot √ 2.$$

The second ratio of growth rates can include a ratio proportional to the growth rate of the material in [100] direction to the growth rate of the material in the [110] direction. In another example, the third ratio of growth rates is defined by

$$γ = \frac{{V}_{[ 100 ]}}{{V}_{[ 113 ]}} \cdot √ 11.$$

The third ratio of growth rates can include a ratio proportional to the growth rate of the material in [100] direction to the growth rate of the material in the [113] direction. The ratio of growth rates can include a ratio proportional to the growth rate of the material in a first direction to the growth rate of the material in a second direction different from the first direction. The method 500 can include calculating the plurality of ratios of growth rates based on atomic force microscopy characterization of template overgrowth. In some embodiments, the growth rates can be predetermined. For example, the growth rates can include predetermined growth rates. The ratio of the growth rates can be determined based on experimental determination of growth times for a set of growth conditions.

The method 500 can include etching an array of pits (BLOCK 510). For example, the method 500 includes etching an array of pits into a first portion of a substrate. The first portion of the substrate can include the patterned [001] face. The first portion of the substrate can include the patterned portion of the substrate. The substrate can include diamond (e.g., single crystal diamond). The method 500 can include exposing one or more surfaces of the substrate. For example, the method 500 can include exposing the [001] surface or the [111] surface. In one example, each pit of the array of pits has a [001] surface exposed. In another example, each pit of the array of pits has a [111] surface exposed. The method 500 can include creating exposed [111] faces on a [001] surface. Etching the array of pits can include isotropic etching (e.g., removing material equally in all directions) and/or non-isotropic etching (e.g., anisotropic etching, removing material in specific directions). In some embodiments, the method 500 includes defining (e.g., demarcating, determining the boundaries of) the array of pits. For example, the array of pits can be defined using lithography. The array of pits can be defined before etching. The array of pits can be etched into the first portion of the substrate subsequent to determining the plurality of ratios of the growth rates.

Each pit of the array of pits can have dimensions that are sub-micron. For example, each pit of the array of pits can have a width that is less than 1 μm. For example, each pit of the array of pits can have a width that is less than 1 μm, less than 900 nm, less than 800 nm, less than 700 nm, less than 600 nm, less than 500 nm, less than 400 nm, less than 300 nm, less than 200 nm, less than 100 nm, or less than 50 nm. In some embodiments, each pit of the array of pits has a width that is equal to or greater than 1 μm. Each pit of the array of pits can have a width in a range of 10 nm to 50 nm, 10 nm to 100 nm, 10 nm to 250 nm, 10 nm to 100 nm, 10 nm to 750 nm, 10 nm to 1 μm, 50 nm to 100 nm, 50 nm to 250 nm, 50 nm to 500 nm, 50 nm to 750 nm, 50 nm to 1 μm, 100 nm to 250 nm, 100 nm to 500 nm, 100 nm to 750 nm, 100 nm to 1 μm, 250 nm to 500 nm, 250 nm to 750 nm, 250 nm to 1 μm, 500 nm to 750 nm, 500 nm to 1 μm, or 750 nm to 1 μm.

In one example, each pit of the array of pits can have a length that is less than 1 μm. For example, each pit of the array of pits can have a length that is less than 1 μm, less than 900 nm, less than 800 nm, less than 700 nm, less than 600 nm, less than 500 nm, less than 400 nm, less than 300 nm, less than 200 nm, less than 100 nm, or less than 50 nm. In some embodiments, each pit of the array of pits has a length that is equal to or greater than 1 μm. The length of each pit of the array of pits can substantially greater than the width of each pit of the array of pits (e.g., 5 times greater, 10 times greater, 25 times greater, 50 times greater). The length of each pit of the array of pits can be substantially greater than the width of each pit of the array of pits to form a line, trench, or line-like pit. The length of each pit of the array of pits can be less than, greater than, or equal to the width of each pit of the array of pits. Each pit of the array of pits can have a length in a range of 10 nm to 50 nm, 10 nm to 100 nm, 10 nm to 250 nm, 10 nm to 100 nm, 10 nm to 750 nm, 10 nm to 1 μm, 50 nm to 100 nm, 50 nm to 250 nm, 50 nm to 500 nm, 50 nm to 750 nm, 50 nm to 1 μm, 100 nm to 250 nm, 100 nm to 500 nm, 100 nm to 750 nm, 100 nm to 1 μm, 250 nm to 500 nm, 250 nm to 750 nm, 250 nm to 1 μm, 500 nm to 750 nm, 500 nm to 1 μm, or 750 nm to 1 μm.

In one example, each pit of the array of pits has a depth that is less than 1 μm. For example, each pit of the array of pits can have a depth that is less than 1 μm, less than 900 nm, less than 800 nm, less than 700 nm, less than 600 nm, less than 500 nm, less than 400 nm, less than 300 nm, less than 200 nm, less than 100 nm, or less than 50 nm. In some embodiments, each pit of the array of pits has a depth that is equal to or greater than 1 μm. Each pit of the array of pits can have a depth in a range of 10 nm to 50 nm, 10 nm to 100 nm, 10 nm to 250 nm, 10 nm to 100 nm, 10 nm to 750 nm, 10 nm to 1 μm, 50 nm to 100 nm, 50 nm to 250 nm, 50 nm to 500 nm, 50 nm to 750 nm, 50 nm to 1 μm, 100 nm to 250 nm, 100 nm to 500 nm, 100 nm to 750 nm, 100 nm to 1 μm, 250 nm to 500 nm, 250 nm to 750 nm, 250 nm to 1 μm, 500 nm to 750 nm, 500 nm to 1 μm, or 750 nm to 1 μm.

The method 500 can include filling the pits with dopant (BLOCK 515). For example, the method 500 includes filling each pit of the array of pits with a dopant. The dopant can include, for example, nitrogen, nitrogen-vacancy centers, germanium, and/or germanium-vacancy centers. The dopant can include a group IV dopant. The dopant can include boron or phosphorus. Each pit of the array of pits can be filled at a first growth rate. The first growth rate can be on the order of microns or nanometers per hour. For example, the first growth rate can be a few microns per hour. In another example, the first growth rate can be a few hundred nanometers per hour. In the pit, the dopant can grow in the [111] direction. For example, the dopant can primarily grow in the [111] direction. The first growth rate can be based on the plurality of ratios of growth rates. Each pit of the array of pits can be filled to form an array of filled pits. The dopant can be localized to the array of filled pits. The array of filled pits can include a plurality of nitrogen-vacancy centers. The array of filled pits can include spin-defects. Each pit of the array of pits can be filled with the dopant subsequent to etching the array of pits into the first portion of the substrate.

The method 500 can include forming an overlayer (BLOCK 520). For example, the method 500 includes forming a portion of an overlayer on a second portion of the substrate. The second portion of the substrate can include the un-patterned [001] face. The second portion of the substrate can include the un-patterned portion of the substrate. The second portion of the substrate can be adjacent to the array of pits. The method 500 can include forming the portion of the overlayer on the second portion of the substrate at a second growth rate. The second growth rate can be on the order of microns or nanometers per hour. For example, the first growth rate can be a few microns per hour. In another example, the first growth rate can be a few nanometers per hour. The second growth rate can less than the first growth rate. On the second portion the substrate, the dopant can grow in the [001] direction. The second growth rate can be less than the first growth rate. For example, the overlayer can grow slower than the pits are filled. The pits can be filled faster than the overlayer is formed. The dopant can grow faster in the [111] direction than in the [001] direction. The depth of the pit can be greater than the thickness of the overlayer. In some embodiments, the second growth rate is equal to or greater than the first growth rate. In one example, the first growth rate is 1.1 to 3.4 times faster than the second growth rate. In another example, the first growth rate is 10 to 30 times faster than the second growth rate. In yet another example, a pit with a depth of 30 nm can be filled while only forming an overlayer on the second portion of the substrate that is 2-4 nm thick. The overlayer can be formed subsequent to filling each pit of the array of pits.

The overlayer can include (1) the portion of the overlayer on the second portion of the substrate and (2) dopant disposed on the array of filled pits. For example, the overlayer can include dopant disposed on the second portion of the substrate. The overlayer can include dopant disposed on each pit of the array of pits. The overlayer can include dopant disposed on the second portion of the substrate. The overlayer can include dopant disposed on the first portion of the substrate.

The method 500 can include removing the overlayer (BLOCK 525). For example, the method 500 includes removing the overlayer to expose the second portion of the substrate. The overlayer can be removed by at least one of reactive-ion etching or plasma etching. The method 500 can allow for the removal of a thin/minimal overlayer (in contrast to a thick overlayer) after filling each pit of the plurality of pits. The method can include removing a portion of the overlayer or the entire overlayer. The method can include removing the overlayer disposed on the second portion of the substrate and on the first portion of the substrate. The overlayer can be removed subsequent to forming the overlayer.

In some embodiments, the method 500 includes depositing the dopant into each pit of the array of pits at a third growth rate. The third growth rate can be based on the plurality of ratios of growth rates. The third growth rate can be greater than, less than, or equal to the first growth rate. The third growth rate can be greater than, less than, or equal to the second growth rate.

In some embodiments, the method 500 includes forming a layer of single crystal diamond on the second portion of the substrate and the first portion of the substrate. In some embodiments, the method 500 includes determining one or more growth regimes of a sample. For example, the method 500 can be used as an analytic tool to study growth. The method 500 can be used to track uniformity of growth across the sample.

The method 500 can be non-destructive (e.g., non-damaging) in that the method 500 does not damage the substrate in areas where no dopant is found. For example, the method 500 can be free of ion implantation, which can be destructive to the substrate in areas where no dopant is found. Electronic grade diamond may need to have imperfections that are limited to the parts-per-billion level, so techniques should not introduce undesired defects beyond tolerances.

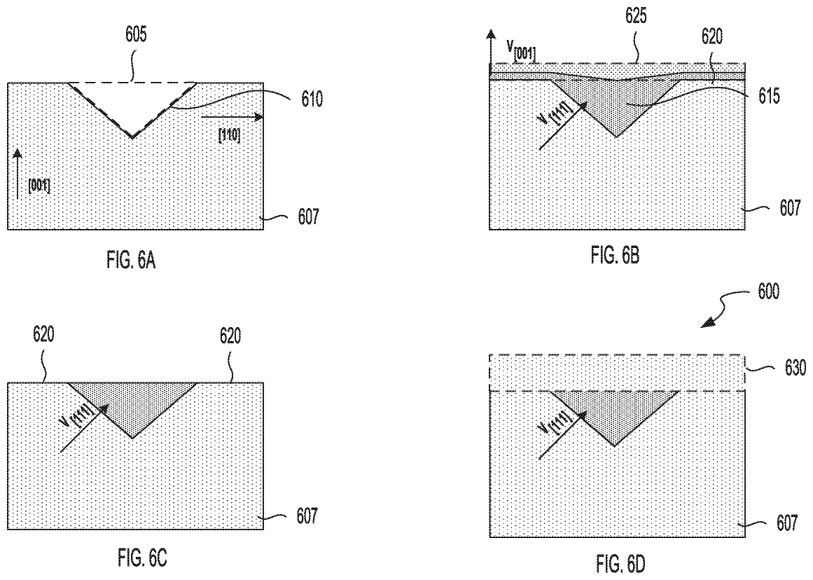

FIGS. 6A-6D illustrate a doped diamond crystal 600 formed by a method for heterogeneous diamond face synthesis. An assembly can include the doped diamond crystal 600. The doped diamond crystal can be used to create a deterministic localized array of sensors (e.g., quantum sensors) or doped arrays for electronic applications. The doped diamond crystal can be formed by the method 500. For example, the doped diamond crystal 600 can be formed by determining a plurality of ratios of growth rates. The doped diamond crystal 600 can be formed by etching an array of pits into a first portion 605 of a substrate 607 as shown in FIG. 6A. The array of pits can be made of a plurality of pits 610 as shown in FIG. 6A. The substrate can include a single crystal diamond. The doped diamond crystal 600 can be formed by filling each pit 610 of the array of pits with a dopant 615 at a first growth rate based on the plurality of ratios of growth rates to form an array of filled pits as shown in FIG. 6B. The doped diamond crystal 600 can be formed by forming a portion of an overlayer 625 on a second portion 620 of the substrate adjacent to the array of pits at a second growth rate less than the first growth rate as shown in FIG. 6B. The doped diamond crystal 600 can be formed by forming the overlayer 625 that includes (1) the portion of the overlayer on the second portion 620 of the substrate and (2) dopant disposed on the array of filled pits as shown in FIG. 6B. The doped diamond crystal 600 can be formed by removing the overlayer to expose the second portion of the substrate as shown in FIG. 6C. The doped diamond crystal 600 can be formed by forming a layer 630 of single crystal diamond on the second portion of the substrate and the first portion of the substrate as shown in FIG. 6D. The layer 630 can include homoepitaxial CVD overgrowth.

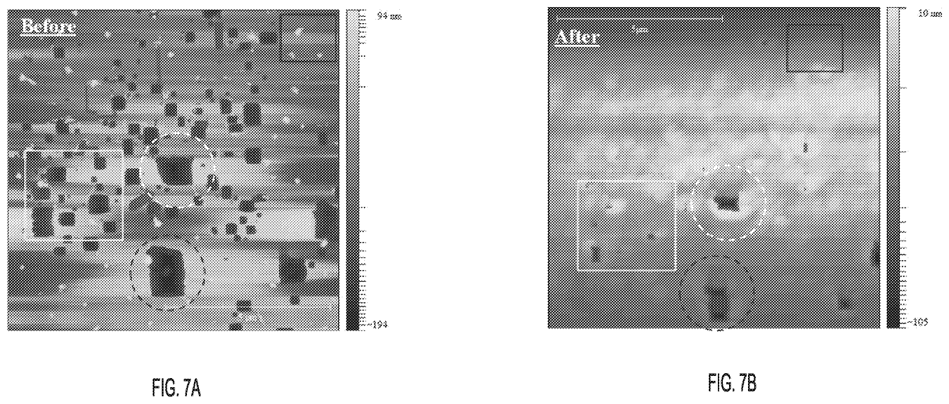

FIGS. 7A and 7B illustrate atomic force microscopy images. FIG. 7A illustrates AFM image before diamond overgrowth and FIG. 7B illustrates an AFM image after diamond overgrowth (e.g., filling of [111] exposed faceted features to leave a pristine [001] surface). The portions of FIGS. 7A and 7B marked by solid rectangles and dashed circles represent co-localization areas. FIGS. 7A and 7B experimentally demonstrate that the method of the present disclosure works at the nanometer scale and that the filling rates can be predicted.

As shown in FIG. 7A, multiple sizes of features were etched into the substrate. Using the different sizes of etched feature, the amount of growth that is needed to fill some of the features while not filling other features could be determined. For example, the largest features were not filled and were not expected to fill, while the smallest features were filled and were expected to fill. The largest features were not homogenized with the remaining [001] surface, while the smallest features formed a homogenized [001] surface.

As shown in FIG. 7B, the areas with the substantially rectangular shape that are enclosed by the solid rectangles and the dashed circles represent areas shown in FIG. 7A that did not fill to a pristine [001] surface. The geometry of the features to be filled can be controlled. The [111] face and [001] face growth rates can be characterized for various growth conditions. The growth conditions can include conditions suitable for growing single crystal diamond. The ratio of the [111] face and [001] face growth rates can be proportional to the parameter a.

No claim element herein is to be construed under the provisions of 35 U.S.C. § 112(f), unless the element is expressly recited using the phrase “means for.”

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic. For example, circuit A communicably “coupled” to circuit B may signify that the circuit A communicates directly with circuit B (i.e., no intermediary) or communicates indirectly with circuit B (e.g., through one or more intermediaries).

As used herein, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

The term “or,” as used herein, is used in its inclusive sense (and not in its exclusive sense) so that when used to connect a list of elements, the term “or” means one, some, or all of the elements in the list. Conjunctive language such as the phrase “at least one of X, Y, and Z,” unless specifically stated otherwise, is understood to convey that an element may be either X, Y, Z; X and Y; X and Z; Y and Z; or X, Y, and Z (i.e., any combination of X, Y, and Z). Thus, such conjunctive language is not generally intended to imply that certain embodiments require at least one of X, at least one of Y, and at least one of Z to each be present, unless otherwise indicated.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Although the figures and description may illustrate a specific order of method steps, the order of such steps may differ from what is depicted and described, unless specified differently above. Also, two or more steps may be performed concurrently or with partial concurrence, unless specified differently above.

It is important to note that any element disclosed in one embodiment may be incorporated or utilized with any other embodiment disclosed herein. Although only one example of an element from one embodiment that can be incorporated or utilized in another embodiment has been described above, it should be appreciated that other elements of the various embodiments may be incorporated or utilized with any of the other embodiments disclosed herein.

What is claimed:

1. A method, comprising:
determining a plurality of ratios of growth rates;
etching an array of pits into a first portion of a substrate comprising single crystal diamond;
filling each pit of the array of pits with a dopant at a first growth rate based on the plurality of ratios of growth rates to form an array of filled pits;
forming a portion of an overlayer on a second portion of the substrate adjacent to the array of pits at a second growth rate less than the first growth rate, wherein the overlayer comprises (1) the portion of the overlayer on the second portion of the substrate and (2) dopant disposed on the array of filled pits; and
removing the overlayer to expose the second portion of the substrate.

2. The method of claim 1, wherein:
the plurality of ratios of growth rates comprises a first ratio of growth rates, a second ratio of growth rates, and a third ratio of growth rates;
the first ratio of growth rates is defined by
$$α = \frac{{V}_{[ 100 ]}}{{V}_{[ 111 ]}} \cdot √ 3 ;$$
the second ratio of growth rates is defined by
$$β = \frac{{V}_{[ 100 ]}}{{V}_{[ 110 ]}} \cdot √ 2 ;$$
and
the third ratio of growth rates is defined by
$$γ = \frac{{V}_{[ 100 ]}}{{V}_{[ 113 ]}} \cdot √ 11.$$

3. The method of claim 1, comprising:
defining, using lithography, the array of pits.

4. The method of claim 1, comprising:
depositing the dopant into each pit of the array of pits at a third growth rate based on the plurality of ratios of growth rates.

5. The method of claim 1, comprising:
forming a layer of single crystal diamond on the second portion of the substrate and the first portion of the substrate.

6. The method of claim 1, wherein each pit of the array of pits has a [001] surface exposed.

7. The method of claim 1, wherein each pit of the array of pits has a [111] surface exposed.

8. The method of claim 1, wherein each pit of the array of pits has a width that is less than 1 μm.

9. The method of claim 1, wherein each pit of the array of pits has a depth that is less than 1 μm.

10. The method of claim 1, wherein the first growth rate is 1.1 to 3.4 times faster than the second growth rate.

11. The method of claim 1, wherein the overlayer is removed by at least one of reactive-ion etching or plasma etching.

12. The method of claim 1, wherein the dopant is localized to the array of filled pits.

13. The method of claim 1, wherein the array of filled pits comprise a plurality of nitrogen-vacancy centers.

14. The method of claim 1, wherein the method does not use ion implantation.

15. The method of claim 1, comprising:
calculating the plurality of ratios of growth rates based on atomic force microscopy characterization of template overgrowth.

16. The method of claim 1, wherein etching the array of pits comprises isotropic and non-isotropic etching.

17. An assembly, comprising:
a doped diamond crystal formed by:
determining a plurality of ratios of growth rates;
etching an array of pits into a first portion of a substrate comprising single crystal diamond;
filling each pit of the array of pits with a dopant at a first growth rate based on the plurality of ratios of growth rates to form an array of filled pits;
forming a portion of an overlayer on a second portion of the substrate adjacent to the array of pits at a second growth rate less than the first growth rate, wherein the overlayer comprises (1) the portion of the overlayer on the second portion of the substrate and (2) dopant disposed on the array of filled pits; and
removing the overlayer to expose the second portion of the substrate.

18. The assembly of claim 17, wherein:
the plurality of ratios of growth rates comprises a first ratio of growth rates, a second ratio of growth rates, and a third ratio of growth rates;
the first ratio of growth rates is defined by
$$α = \frac{{V}_{[ 100 ]}}{{V}_{[ 111 ]}} \cdot √ 3 ;$$
the second ratio of growth rates is defined by
$$β = \frac{{V}_{[ 100 ]}}{{V}_{[ 110 ]}} \cdot √ 2 ;$$
and
the third ratio of growth rates is defined by
$$γ = \frac{{V}_{[ 100 ]}}{{V}_{[ 113 ]}} \cdot √ 11.$$

19. The assembly of claim 17, wherein each pit of the array of pits has a width that is less than 1 μm.

20. The assembly of claim 17, wherein each pit of the array of pits has a depth that is less than 1 μm.
